(19) United States
(12) Patent Application Publication
(10) Pub. No.: US 2016/0084673 A1
(43) Pub. Date: Mar. 24, 2016

(54) WIRELESS MVT SENSOR

(71) Applicants: Paul Mayer, Granville, MA (US); Xuedong Liu, Avon, CT (US)

(72) Inventors: Paul Mayer, Granville, MA (US); Xuedong Liu, Avon, CT (US)

(73) Assignee: NEWGATE INSTRUMENTS, LLC, EAST GRANBY, CT (US)

(21) Appl. No.: 14/860,787

(22) Filed: Sep. 22, 2015

Related U.S. Application Data
(60) Provisional application No. 62/053,304, filed on Sep. 22, 2014.

(51) Int. Cl. G01D 4/02; H02J 7/35; G01L 9/00; H05K 5/00

(52) U.S. Cl. CPC G01D 4/02; H05K 5/0017; H02J 7/355; G01L 9/0052

(57) ABSTRACT

A small-footprint and low-power MVT system includes an explosion-proof housing, a high impedance piezo-resistive sensor contained within the housing for measuring at least one parameter of a fluid, an integrated battery storage unit, and an array of solar cells within the housing configured to collect ambient light and to recharge the battery storage unit.

### CROSS-REFERENCE TO RELATED APPLICATIONS

This application claims the benefit of U.S. Provisional Application Ser. No. 62/053,304, filed on Sep. 22, 2014, which is herein incorporated by reference in its entirety.

### FIELD OF THE INVENTION

The invention relates generally to sensor apparatus for installation on natural gas pipelines. Particular embodiments relate to an autonomous sensor apparatus for installation and high endurance operation in remote locations.

### BACKGROUND OF THE INVENTION

Multi-variable transmitters (MVTs) are powered sensors that are installed on natural gas pipelines to monitor a variety of parameters, including flow velocity and volume. Often, it is desirable to monitor pipeline parameters at locations remote from any power source or control station. However, costs for providing power to a remote MVT, and for obtaining a signal from the remote MVT, can be extremely high.

Conventional remote MVT installations have required external antenna, power and radio connections, which consume significant power (e.g., 60 to 100 mW when operating), which has driven a need for external power feed and at least 12-V battery power. Accordingly, conventional remote MVTs have provided an extended period of time between transmissions for practical battery life and have therefore not updated data often enough to meet API standards.

Even in case the cost of running power and data cables to a remote location is not prohibitive, it still is desirable to provide autonomous power to a remote sensor (e.g., a battery). In case autonomous power is provided, it may be desirable to eliminate the cost of running power cabling by providing autonomous power sources (e.g., solar power charging a battery). Also, it may be desirable to eliminate the cost of running data cabling by providing wireless data transmission.

### SUMMARY OF THE INVENTION

It is an object of the present invention to provide a wireless MVT sensor.

It is another object of the present invention to provide a wireless MVT sensor having an autonomous power source.

It is another object of the present invention to provide a wireless MVT sensor configured for wireless data transmission.

In order to reduce the size of the battery required for autonomous operation, while extending a sensor package's autonomous endurance, it is also desirable to obtain sufficient solar power to recharge the battery pack. At the same time, it is generally desirable to provide a sensor package of minimum overall weight and dimensions. This goal is particularly desirable for a measurement system to be installed at remote locations, where any reduction of weight or size will significantly and positively impact Total Cost of Operation.

These and other objects are achieved by the present invention.

In embodiments of the invention, a small-footprint and low-power MVT system (including a high impedance piezo-resistive sensor) is provided with an integrated battery storage unit that may be rechargeable from a solar cell also housed within the same explosion-proof housing. For enhanced efficiency of solar collection, the system may be provided with a light scoop.

### BRIEF DESCRIPTION OF THE DRAWINGS

The present invention will be better understood from reading the following description of non-limiting embodiments, with reference to the attached drawings, wherein below:

FIG. 1 shows in perspective an MVT sensor package with light scoop, according to an embodiment of the invention.

FIG. 2 is a front elevational view of the MVT sensor package of FIG. 1.

FIG. 3 shows in schematic the MVT sensor package of FIG. 1.

FIG. 4 shows in perspective the MVT sensor package of FIG. 1, side by side with a conventional MVT sensor package including a discrete solar panel, external power unit, and antenna.

### DETAILED DESCRIPTION OF THE PREFERRED EMBODIMENT

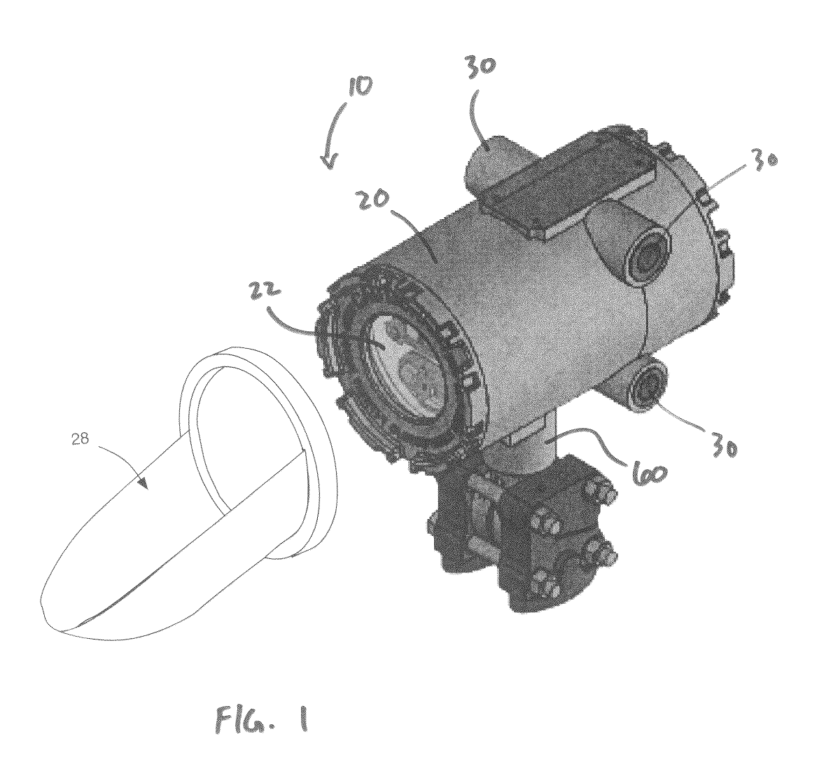

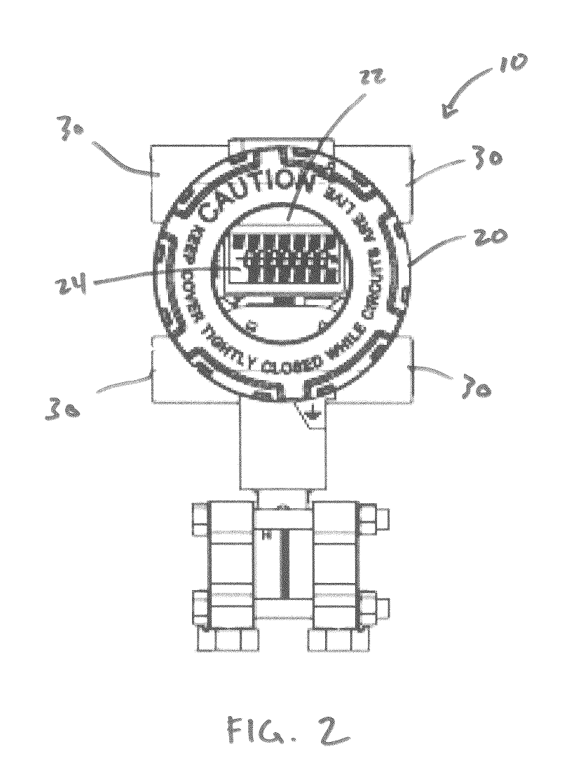

With reference to FIGS. 1 and 2, an MVT sensor package 10 according to an embodiment of the invention includes is illustrated. The MVT sensor package 10 includes a generally cylindrically shaped explosion-proof housing 20. The housing 20 is provided at its forward end with a first transparent window 22 through which an operator can view a digital readout of measured values on a display screen 24 contained within the housing 20, as discussed hereinafter, and at its rearward end with a second transparent window 26, the purpose of which will be discussed hereinafter. As also shown in FIG. 1, the MVT sensor package may include a light scoop 28 that is removably received by the housing 20. As shown therein, the light scoop 28 contains a canoe-shaped trough having a reflective inner surface and is adapted to mount to one end of the housing 20. As also shown in FIGS. 1 and 2, the housing 20 includes conduit fittings 30 for connecting to the RTD or other external input/output ports.

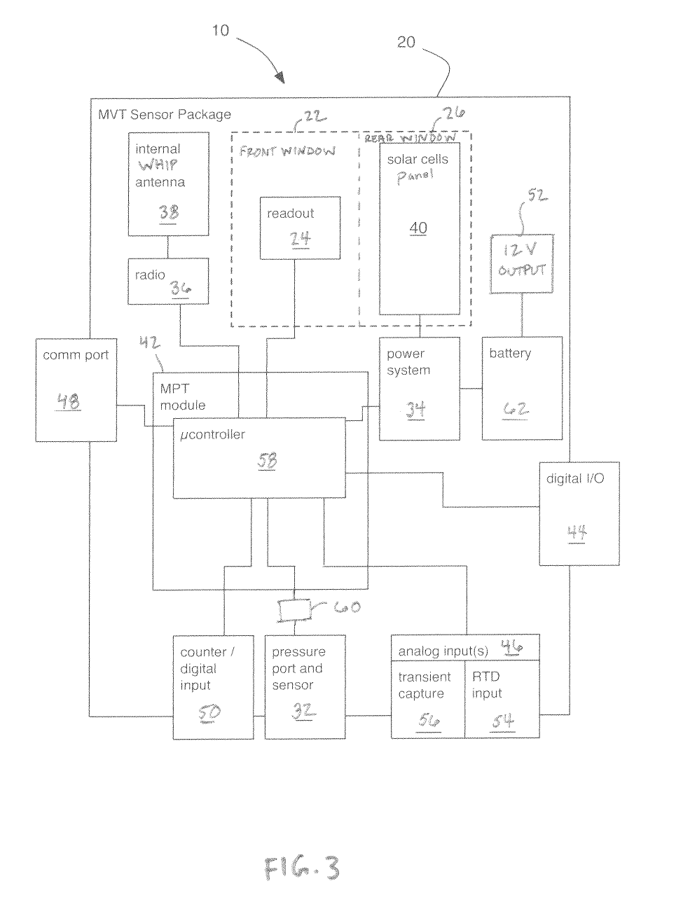

Referring now to FIG. 3, the internal components of the MVT sensor package 10 are schematically illustrated. As shown therein, within the housing 20 of the sensor package 10 are contained a differential/static pressure sensor module 32, an integrated power system 34, a radio 36 and antenna 38, as well as one or more input/output (I/O) ports. An optional solar panel 40 is positioned within the housing adjacent the rear window 26 and is configured to receive solar energy therethrough. As alluded to above, when configured with the light scoop 28, the light scoop 28 is configured to concentrate ambient light onto the solar panel 40 behind the window 26.

In an embodiment, the MVT sensor package 10 provides a remote measurement platform that combines a precision multivariable pressure transmitter (MPT) module 42 with the integrated power system 34 and a radio 36. The MVT sensor package 10 also includes digital I/O ports 44, one or two analog inputs 46, at least one communications port 48, a high speed counter input 50 (which can double as a digital input), a 12-volt stepped-up power source 52, an RTD input 54, and a transient capture input 56.

The MVT sensor package 10 is designed specifically for ultra-low power operation from the ground-up. The MVT module 42 incorporates a microcontroller 58, which switches voltage to a high impedance single crystal silicon micro-machined pressure (piezo-resistive) sensor 60 in order to obtain quick pressure readings by briefly applying power during each measurement cycle, thereby optimizing power consumption. Due to the high impedance of the piezo-resistive sensor 60, the microcontroller 58 does not need to allow for any warm-up or stabilization time after power application, which minimizes the duration of each measurement conversion cycle. Additionally, the high impedance results in lower operating current draw, permitting the sensor package 10 to utilize a battery pack 62 with smaller than conventional energy storage capacity.

In an embodiment, the microcontroller 58 may be configured to carry out pressure measurement once per second in order to be compliant with API chapter 21 metrology requirements. However, self-calibration and temperature compensation measurements, which change at a rate that is orders of magnitudes lower than pressure signal, are staggered through multiple (e.g., four) one-second measurement cycles in order to further reduce on-time and therefore save more power. All peripheral functions and options can be turned off when not in use, including the microcontroller 58 itself.

Importantly, the configuration discussed above permits the entire measurement and data logging system (MVT sensor package 10) to operate using no more than about 175 microamperes of daily average current. Incorporating a commercially available radio transmitter 36, as shown, and using the radio to transmit data every 15 minutes, would add an additional 14 microamperes to the average daily current consumption.

Accounting for temperature effects, radio re-tries, and a design tolerance, system daily average current use may be conservatively estimated at less than 1 miliamperes, which can be supplied from a 4-V lead-acid battery pack 62, translating to average power consumption of 4 mW, so that a 2.5 A-H battery pack would provide 100 days autonomy.

Use of high purity lead-acid batteries 62 provides an additional benefit in that the self-leakage rate of such batteries is in the range of 100 microamperes. To maintain a full charge, the MVT sensor package 10 requires an average daily current of 1,000 microamperes for the electronics plus 100 microamperes for the battery leakage which is 1,000 uA or 26 mA-Hrs per day. Through testing we have discovered that single-crystal solar cells 40, arranged in a pattern where most of the cell area appears through the glass of the windowed cover 26, can scavenge about 6 mA from a 6-V 350 mW panel for at least 8 hours per autumn day from indirect light. This 48 mA-Hrs is more than enough to fully charge the system. In addition, the light scoop 28 can improve solar cell yield by concentrating more light onto the solar cells 40, so that the average current during charging is 8-10 mA. As shown in FIG. 3, charging system 34, including over-charge protection, is built into the MVT sensor package 10.

As an alternative to the lead-acid battery pack 62, the sensor package 10 may include a non-rechargeable 19 A-H Lithium Thionyl Chloride battery pack to provide over five years autonomy. In this case the solar cells 40 would not recharge the battery pack but instead would load share, i.e., during daylight the solar cells 40 would carry most or all electrical load whereas when light is not available the battery pack would carry the electrical load.

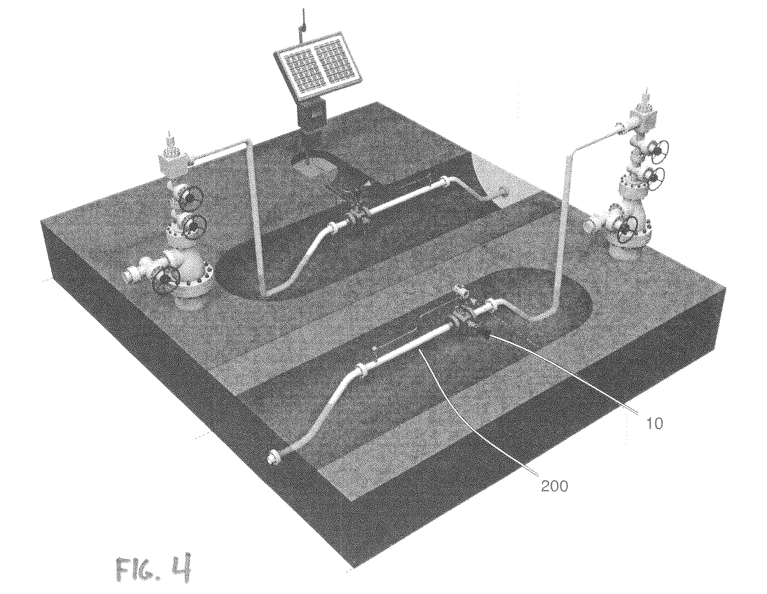

Thus, the inventive MVT sensor package 10 combines the sensor 60, electronics 58, power system 34, and solar cells 40 into the explosion-proof (Class I DIV I) housing 20 that can be mounted by itself onto an orifice-plate meter run 200 of a natural gas well collection or transmission pipeline, as illustrated in FIG. 4.

Importantly, as alluded to above, the MVT sensor package 10 also incorporates the radio communications (i.e., radio 36 and antenna 38) within the housing 20. In operation, the CPU (e.g., microcontroller 58) sporadically activates the radio 36 to transmit an accumulated average of DP, SP, process temperature and extensions with a time stamp necessary for a receiving RTU to make gas flow calculations. The CPU 58 also can store over 35 days of 15-minute averages, so that local data download via I/O connections 44 or 48 also are possible using a laptop computer, PDA, or smartphone.

The radio 36 has an option of an integral whip antenna 38 that is placed within the housing 20, using calculations from electromagnetic theory such that the antenna 38 is exactly one quarter-wavelength from the conductive terminal plate forming an end cap of a circular waveguide along with the housing cylindrical inner surface. Such a configuration constitutes a “tin-can antenna” design that transmits through the display window 22 to provide up to 10 dB or more directional gain while keeping the antenna safely contained within the housing. Thus, there is no need for an external antenna (which nonetheless can be connected via the conduit 30).

As the sensor package 10 operates at relatively low voltage (4 V), it is inherently intrinsically safe and enables use of the battery pack 62 that is small enough to be practically packaged within the housing 20.

Alternatively, the MVT sensor package 10 also can be operated as a stand-alone wired transmitter with RS-485, RS-232 or 4-20 mA FSK communications using external power.

Alternatively, the Differential/Static sensor module may be replaced by a static pressure only module.

Advantageously, an MVT according to an embodiment of the invention provides communication via a local USB port. Advantageously, an MVT according to an embodiment of the invention provides a 12-V output capable of driving solenoid pilot valves.

The additional features, I/O, two-way communication, and the like, can increase current consumption, however the microcontroller CPU 58 is configured to make infrequent use of them so their impact on battery life and autonomy should be minimal. Yet, they are there when needed so custom application in remote sites may very effectively use the platform.

As alluded to above, the MVT sensor package 10 of the present invention provides an integrated solar panel 40 configured to recharge battery pack 62, thus enhancing the efficiency of solar collection and reducing the package volume required for battery storage. Accordingly, this minimizes overall weight and footprint of the package 10, as a whole. According, these features allow the package 10 to be installed at remote locations, where any reduction of weight or size will significantly and positively impact Total Cost of Operation.

Moreover, using a lower-voltage sensor component, such as a high impedance piezo-resistive element in place of conventional strain gage sensors or the like, reduces both operating voltage and total energy storage requirements, thereby also permitting reduction of package volume for energy collection and storage.

Although this invention has been shown and described with respect to the detailed embodiments thereof, it will be understood by those of skill in the art that various changes may be made and equivalents may be substituted for elements thereof without departing from the scope of the invention. In addition, modifications may be made to adapt a particular situation or material to the teachings of the invention without departing from the essential scope thereof. Therefore, it is intended that the invention not be limited to the particular embodiments disclosed in the above detailed description, but that the invention will include all embodiments falling within the scope of this disclosure.

What is claimed is:

1. A multi-variable transmitter, comprising:
a housing;
a high impedance piezo-resistive sensor contained with the housing, the sensor being configured to monitor at least one parameter of a fluid during a measurement cycle;
a battery pack contained within the housing, the battery providing a source of power;
a controller contained within the housing and configured to selectively provide power from the battery pack to the sensor during the measurement cycle; and
a radio transmitter configured to transmit measured data to a remote location under control of the controller.

2. The multi-variable transmitter of claim 1, wherein:
the at least one parameter includes a pressure of the fluid.

3. The multi-variable transmitter of claim 2, wherein:
the at least one parameter includes a flow velocity and volume of the fluid.

4. The multi-variable transmitter of claim 2, wherein:
the housing is an explosion-proof housing;
the housing includes a first end provided with a first transparent window and a second end opposite the first end provided with a second transparent window.

5. The multi-variable transmitter of claim 2, further comprising:
a display screen electrically connected to the controller and positioned within the housing behind the first transparent window, the display screen being configured to display values relating to the measured data under control of the controller.

6. The multi-variable transmitter of claim 5, further comprising:
a solar panel in electrical communication with the battery pack and positioned within the housing behind the second transparent window, the solar panel being configured to collect solar energy and to recharge the battery pack.

7. The multi-variable transmitter of claim 6, further comprising:
a light scoop mounted to the housing and being configured to concentrate ambient light onto the solar panel.

8. The multi-variable transmitter of claim 1, wherein:
the transmitter is configured to carry out a pressure measurement approximately once per second; and
the transmitter is configured to utilize no more than about 175 microamperes of daily average current for measurement and data logging functions.

9. The multi-variable transmitter of claim 1, wherein:
the batter pack includes at least one lead-acid battery.

10. The multi-variable transmitter of claim 1, wherein:
the controller is configured to intermittently activate the radio transmitter to transmit an accumulated average DP, SP and process temperature measurements to the remote location.

11. The multi-variable transmitter of claim 1, further comprising:
a plurality of input/output ports in electrically communication with the controller, the ports being configured to facilitate local download of the measured data.

12. The multi-variable transmitter of claim 1, further comprising:
a whip antenna integrated within the housing an electrically connected to the radio transmitter.

13. The multi-variable transmitter of claim 12, wherein:
the housing is generally cylindrical in shape.

14. A multi-variable transmitter system, comprising:
a generally cylindrical housing;
a sensor contained with the housing, the sensor being configured to monitor at least one parameter of a fluid during a measurement cycle;
a battery pack contained within the housing;
a controller contained within the housing and configured to selectively provide power from the battery pack to the sensor during the measurement cycle; and
an array of solar cells contained within the housing, the solar cells being configured to recharge the battery pack.

15. The multi-variable transmitter system of claim 14, wherein:
the sensor is a high impedance piezo-resistive sensor.

16. The multi-variable transmitter system of claim 15, further comprising:
a radio transmitter within the housing, the radio transmitter being configured to transmit measured data to a remote location under control of the controller.

17. The multi-variable transmitter system of claim 16, wherein:
the radio transmitter includes a whip antenna.

18. The multi-variable transmitter system of claim 16, wherein:
the housing is an explosion-proof housing;
the housing includes a first end provided with a first transparent window and a second end opposite the first end provided with a second transparent window.

19. The multi-variable transmitter system of claim 18, further comprising:
a display screen electrically connected to the controller and positioned within the housing behind the first transparent window, the display screen being configured to display values relating to the measured data under control of the control unit.

20. The multi-variable transmitter system of claim 15, further comprising:
a light scoop mounted to the housing and being configured to concentrate ambient light onto the solar cells.
